(19) United States
(12) Patent Application Publication
(10) Pub. No.: US 2005/0179067 A1
(43) Pub. Date: Aug. 18, 2005

(54) Semiconductor device and fabricating method thereof

(76) Inventor: Myung Kun Song, Seodaemun-gu (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/021,406

(22) Filed: Dec. 23, 2004

(30) Foreign Application Priority Data
Dec. 24, 2003 (KR) 2003-0096995

(51) Int. Cl. H01L 21/336; H01L 21/8234; H01L 29/76; H01L 31/062

(52) U.S. Cl. 257/288; 438/197; 438/306; 257/408

(57) ABSTRACT

A semiconductor device and fabricating method thereof in which a drain-source breakdown voltage is improved by additional ion implantation into a lightly doped drain are disclosed. An example method of fabricating a semiconductor device includes forming a gate having a gate oxide underneath on a semiconductor substrate, forming a first LDD region in the semiconductor substrate by first ion implantation using the gate as a mask, forming a second first LDD region in the semiconductor substrate by second ion implantation using the gate as a mask, and forming a third LDD region within the first and second LDD regions by third ion implantation.

### RELATED APPLICATION

This application claims the benefit of Korean Application No. P2003-0096995 filed on Dec. 24, 2003, which is hereby incorporated herein by reference in its entirety.

### TECHNICAL FIELD

The present disclosure relates to a semiconductor device and, more particularly, to a semiconductor device and fabricating method thereof in which a drain-source breakdown voltage is improved by additional ion implantation into a lightly doped drain.

### BACKGROUND

Generally, semiconductor devices have become more highly integrated with better performance but are accompanied with new problems that have to be solved. For instance, a quantity of ions implanted into a semiconductor substrate is typically increased to sustain a characteristic and performance of a short channel device, whereby a junction generating a big electric field is formed. This leads to defects within the device and, specifically, to a problem of hot carrier generation. To solve the hot carrier problem, LDD (lightly doped drain) ion implantation is additionally carried out. In the LDD ion implantation, As ions are implanted into an NMOS device or P ions are additionally implanted therein, whereby a gradient LDD junction is formed to solve the hot carrier problem.

As a characteristic for evaluating an LDD semiconductor device to solve the hot carrier problem, there is a breakdown voltage drain source substrate (BVDSS). Thus, a better BVDSS characteristic is desirable to improve an LLD semiconductor device.

FIG. 1A and FIG. 1B are cross-sectional diagrams of known LDD semiconductor devices, respectively. Referring to FIG. 1A, a device isolation layer 16, a gate oxide layer 12, a gate 13, a source 14, and a drain 15 are formed on a semiconductor substrate 11. Additionally, LDD regions 17 are provided to the substrate 11 between the gate 13 and the source and drain 14 and 15, respectively. Specifically, the LDD regions 17 are formed by As or P ion implantation using the gate 13 as an ion implantation mask.

Alternatively, LDD regions 17 and 18, as shown in FIG. 1B, can be formed by implanting both of As and P ions into the substrate. Substantially, first ion implantation is carried out on the substrate 11 using As or P ions to form first LDD regions 17. Second ion implantation is then carried out on the substrate 11 using both of the As and P ions to form second LDD regions 18. However, in case of adjusting ion implantation conditions for BVDSS improvement, the As ion having a relatively heavy atomic weight may change other characteristics of the semiconductor device.

### BRIEF DESCRIPTION OF THE DRAWINGS

FIG. 1A and FIG. 1B are cross-sectional diagrams of known LDD semiconductor devices.

FIG. 2 is a cross-sectional diagram of an example semiconductor device having an enhanced drain-source breakdown voltage.

FIG. 3 is a cross-sectional diagram of an LDD region of the example semiconductor device in FIG. 2.

FIG. 4 is an example graph of drain-source breakdown voltage enhanced in case of additional P ion implantation.

FIG. 5 is an example graph of drain saturation current (Idsat) in case of additional P ion plantation.

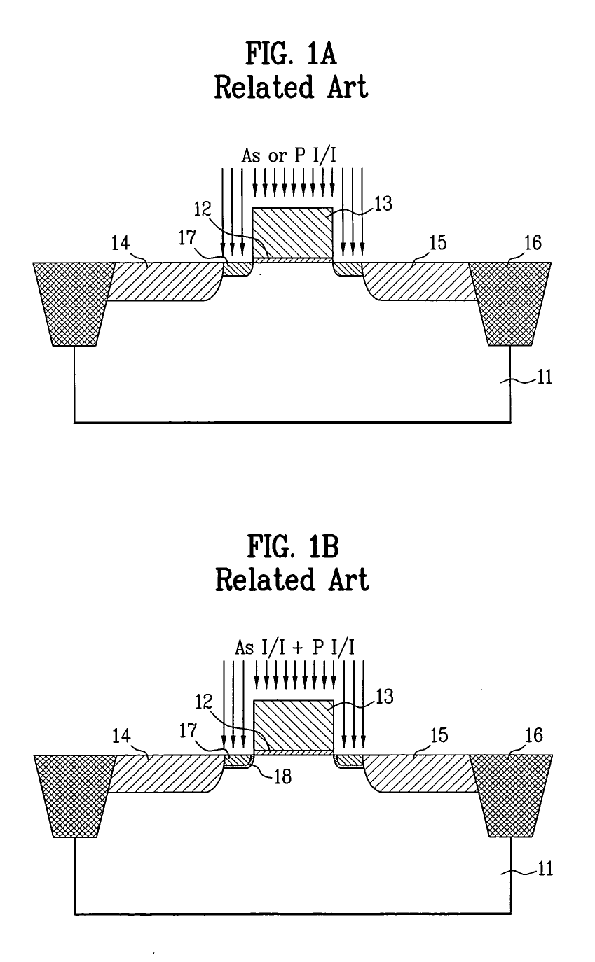

### DETAILED DESCRIPTION

In general, the example methods and apparatus described herein provide a semiconductor device and fabricating method thereof in which a lightly doped drain is additionally doped with impurities to form a gradient junction and by which a drain-source breakdown voltage (BVDSS) is enhanced.

An example method includes forming a gate having a gate oxide underneath on a semiconductor substrate, forming a first LDD region in the semiconductor substrate by first ion implantation using the gate as a mask, forming a second first LDD region in the semiconductor substrate by first ion implantation using the gate as a mask, and forming a third LDD region within the first and second LDD regions by third ion implantation. Preferably, the method further includes forming a source/drain region in the semiconductor substrate to be aligned with the gate and to leave the first to third LDD regions in-between. Preferably, the third ion implantation is carried out using P impurity ions and the third ion implantation is carried out at a dose of 0.5E13˜1.5E13 ions/cm³ with depth energy of 15˜20 KeV. Also preferably, the third LDD region is aligned between the first and second LDD regions.

In another example, a semiconductor device includes a gate having a gate oxide underneath on a semiconductor substrate, a first LDD region in the semiconductor substrate to be aligned with the gate, a second first LDD region enclosing the first LDD region in the semiconductor substrate, a third LDD region aligned between the first and second LDD regions in the semiconductor substrate, and a source/drain region in the semiconductor substrate to be aligned with the gate and to leave the first to third LDD regions in-between. Preferably, the third LDD region is doped with P ions and the third LDD region is doped with the P ions by ion implantation at a dose of 0.5E13˜1.5E13 ions/cm³ with depth energy of 15˜20 KeV.

In the examples described herein, impurities are additionally implanted into LDD regions of a semiconductor device to adjust P density only, whereby the BVDSS characteristic is enhanced without changing other characteristics of the semiconductor device.

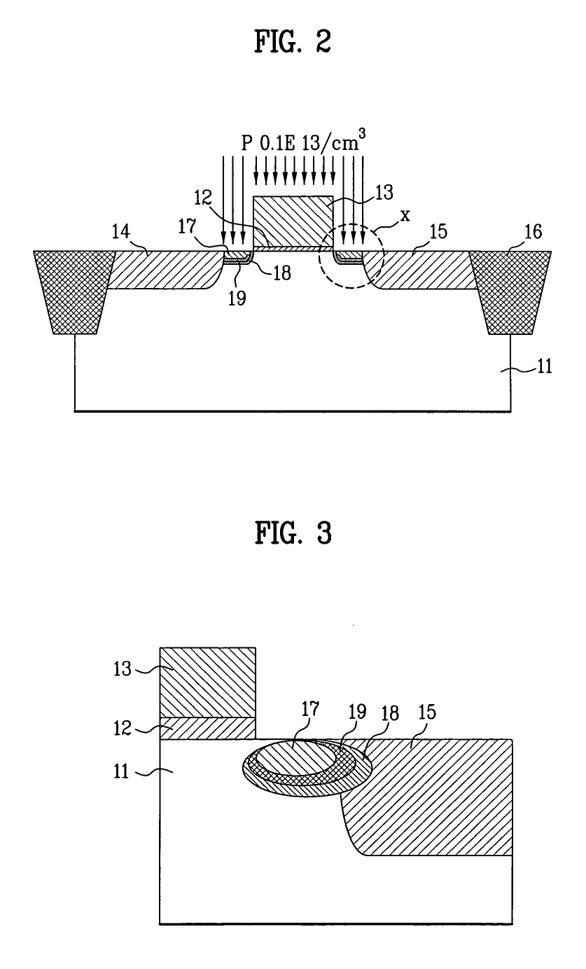

FIG. 2 is a cross-sectional diagram of an example semiconductor device having an enhanced drain-source breakdown voltage and FIG. 3 is a cross-sectional diagram of an LDD region of the example semiconductor device shown in FIG. 2. Referring to FIG. 2 and FIG. 3, LDD regions 17 and 18 are formed by implanting As and P ions into a substrate 11. Specifically, a first ion implantation is carried out on the substrate 11 using As or P ions to form first LDD regions 17. A second ion implantation is then carried out on the substrate 11 using both of the As and P ions to form the second LDD regions 18.

A method of forming a semiconductor device includes forming a gate oxide layer 12 on an active area of a semiconductor substrate 11, forming a gate 13 on the gate oxide layer 12, forming first LDD regions 17 in the active area of the substrate 11 by carrying out a first ion implantation with As or P ions using the gate 13 as an ion implantation mask, forming second LDD regions 18 in the active area of the substrate 11 by carrying out a second ion implantation with both of the As and P ions using the gate 13 as an ion implantation mask, forming third LDD regions 19 in the active area of the substrate 11 by carrying out a third ion implantation with the P ions only using the gate 13 as an ion implantation mask, and forming a source 14 and a drain 15 to be aligned with the gate 13 by leaving the first to third LDD regions 17 to 19 in-between.

Specifically, in forming the third LDD regions 19, an As or P dose is lowered by one order but ion implantation energy is raised by an additional 5˜10 KeV to be higher than that typically used in known processes. With the ion implantation conditions, the third LDD regions 19 are formed in the LDD regions within semiconductor device to provide the optimal doped regions for BVDSS performance enhancement. The third LDD region 19 provides a gradient junction having a desirable breakdown voltage characteristic.

In other words, the additional P ion implantation, as shown in FIG. 2, is performed using the prescribed conditions. Additionally, the doping profiles 17 to 19, as shown in FIG. 3, are formed in the LDD region within the semiconductor device. Although the first and second LDD regions 17 and 18 are formed by the conventional method, the third LDD regions 19 are additionally formed by an example method disclosed herein to provide the optimal doped regions. Hence, the doping junction described herein is smoother than that of known devices in terms of the BVDSS performance. In particular, using the example fabrication methods described herein, the BVDSS characteristic can be enhanced without changing other characteristics of the semiconductor device. Specifically, in the case of providing an improved BVDSS in an NMOS device or in a case of intending to secure drain saturation current (Idsat) of higher output, the third ion implantation is carried out at a dose of about 1.0E13 ions/cm³ with about 20 KeV depth energy.

For the comparison between the examples disclosed herein and known devices and methods, a pair of 10 μm×0.1 μm semiconductor device samples are employed. After completion of performing LDD ion implantation at an As dose of about 2.0E14 ions/cm³ with about 15 KeV depth energy according to the known method on each of the samples. Additionally, the third ion implantation of the examples described herein is carried out on the sample at a dose of about 1.0E13 ions/cm³ with about 20 KeV depth energy using the P dopant only.

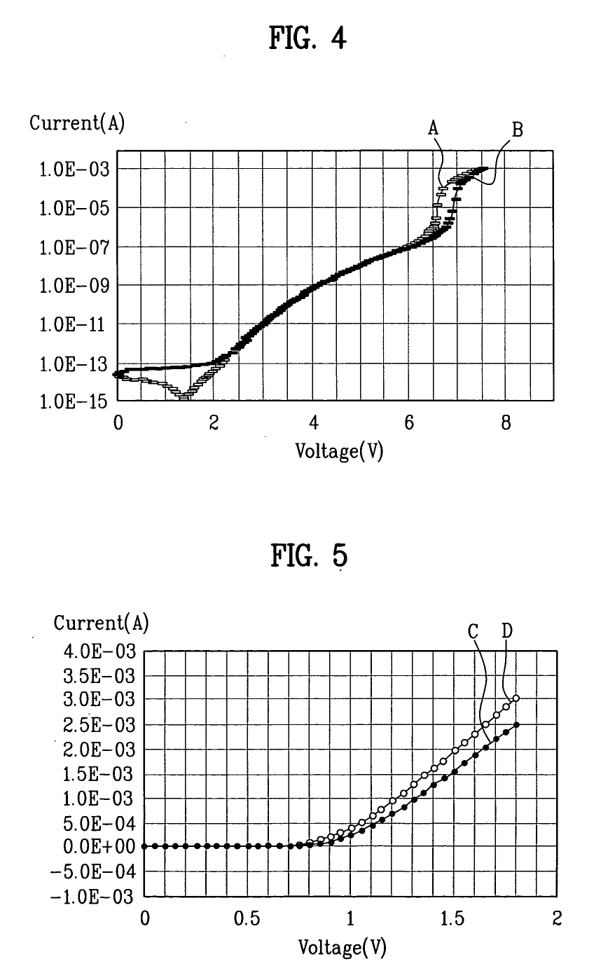

FIG. 4 is an example graph of drain-source breakdown voltage enhanced in case of additional P ion implantation in which a reference letter A indicates BVDSS of a known device and a reference letter B indicates BVDSS of the examples disclosed herein. Referring to FIG. 4, the P impurity ions are additionally implanted at a dose of about 1.0E13 ions/cm³ after completion of the known method, and each BVDSS is measured for comparison. As a result of the comparison, breakdown fails to occur in the examples disclosed herein until a prescribed voltage higher than that of known devices is reached.

FIG. 5 is an example graph of drain saturation current (Idsat) in case of additional P ion implantation in the case of the examples disclosed herein, in which a reference letter C indicates drain saturation current (Idsat) of known devices and a reference letter D indicates drain saturation current (Idsat) of the example devices disclosed herein. Referring to FIG. 5, a higher drain saturation current (Idsat) output is shown in case of performing P ion implantation within a range avoiding device performance shift. Consequently, if the BVDSS performance is degraded in case of ion implantation using As, P, or (As+P) ions to form the LDD, P ions are additionally implanted at a dose lowered by one order within a range of about 1.0E13 ions/cm³. Hence, the example methods described herein can be used to enhance the BVDSS characteristic of a semiconductor device. In one example, P ions are additionally implanted into the LDD region by adjusting a dose of the dopant only, the BVDSS characteristic of the semiconductor device is enhanced without changing other characteristics of the semiconductor device.

Accordingly, using the example methods disclosed herein, impurities are additionally implanted into LDD regions of a semiconductor device to adjust P density only, whereby the BVDSS characteristic is enhanced only without changing other characteristics of the semiconductor device.

While the examples herein have been described in detail with reference to example embodiments, it is to be understood that the coverage of this patent is not limited to the disclosed embodiments, but, on the contrary, is intended to cover various modifications and equivalent arrangements included within the sprit and scope of the appended claims.

1. A method of fabricating a semiconductor device, comprising:
forming a gate having a gate oxide underneath on a semiconductor substrate;
forming a first LDD region in the semiconductor substrate by first ion implantation using the gate as a mask;
forming a second first LDD region in the semiconductor substrate by second ion implantation using the gate as a mask; and
forming a third LDD region within the first and second LDD regions by third ion implantation.

2. The method of claim 1, further comprising forming a source/drain region in the semiconductor substrate to be aligned with the gate and to leave the first to third LDD regions in-between.

3. The method of claim 1, wherein the third ion implantation is carried out using P impurity ions.

4. The method of claim 3, wherein the third ion implantation is carried out at a dose of 0.5E13˜1.5E13 ions/cm³ with depth energy of 15˜20 KeV.

5. The method of claim 4, wherein the third LDD region is aligned between the first and second LDD regions.

6. A semiconductor device comprising:
a gate having a gate oxide underneath on a semiconductor substrate;
a first LDD region in the semiconductor substrate to be aligned with the gate;
a second LDD region enclosing the first LDD region in the semiconductor substrate;
a third LDD region aligned between the first and second LDD regions in the semiconductor substrate; and
a source/drain region in the semiconductor substrate aligned with the gate and to leave the first to third LDD regions in-between.

7. The semiconductor device of claim 6, wherein the third LDD region is doped with P ions.

8. The semiconductor device of claim 7, wherein the third LDD region is doped with the P ions by ion implantation at a dose of 0.5E13˜1.5E13 ions/cm³ with depth energy of 15˜20 KeV.
